(19) United States
(12) Patent Application Publication
(10) Pub. No.: US 2005/0231212 A1
(43) Pub. Date: Oct. 20, 2005

(54) Voltage measurement with automated correction for input impedance errors

(76) Inventors: Oliver C. Moghissi, Dublin, OH (US); Mark Yunovich, Columbus, OH (US)

Correspondence Address: KREMBLAS, FOSTER, PHILLIPS & POLLICK, 7632 SLATE RIDGE BOULEVARD, REYNOLDSBURG, OH, 43068, US

(21) Appl. No.: 10/824,061

(22) Filed: Apr. 14, 2004

(51) Int. Cl. G01R 27/02

(52) U.S. Cl. 324/606

(57) ABSTRACT

An apparatus and method for measuring the potential of a voltage source in a measured circuit having an impedance in the measured circuit. A voltage measuring circuit having an input impedance includes a switchable impedance network for varying the input impedance to a plurality of input impedance values. A microcontroller is connected to the voltage measuring circuit and switches the input impedance, records measured potentials at a plurality on input impedances, solves simultaneous equations, describing the connected measured and voltage measuring circuits, for the potential of the voltage source, and outputs a signal representing the potential of the voltage source.

### (e) BACKGROUND OF THE INVENTION

1. Field of the Invention

This invention relates generally to measurement of voltages and more particularly relates to accurate measurement of voltages through a high impedance by automatically correcting for errors present in conventional voltage measuring circuits.

2. Description of the Related Art

Voltage measurements are often desirable for a variety of purposes. However, where the voltage is being measured through a high resistance or the voltage of a high impedance device is being measured, error in the voltage measurements occurs because of the high resistance. According to Thevenin's theorem, a circuit with a voltage source is equivalently represented as a series ideal voltage source and impedance. The goal is to measure the voltage of that voltage source. However, only the terminals of the series combination of that voltage source and the high impedance is available to the voltmeter or other voltage measuring circuit and therefore only the voltage across that series combination can be directly measured.

An important example of the need to accurately measure a voltage exists in connection with the use of cathodic protection circuits for protecting buried metal objects. Metal objects are commonly buried in a variety of surrounding environments on the earth. These environments include both solid materials, typically referred to as rock, sand or soil, liquid materials, such as seawater and mixtures of water and solids. Buried metal objects, such as pipelines, are naturally subjected to electrochemical corrosion processes in a buried environment, especially at any defects in their protective coatings. The materials in which the metal objects are buried promote corrosion because those materials are naturally occurring electrolytes. Furthermore, it is the physical contact with such electrolytes that presents this corrosion problem so only some physical contact and not complete burying or submersion is necessary for the corrosion problem to exist. Therefore, in order to simplify the terminology, the term “soil” is used generically to refer to the electrolyte material and the terms “bury” or “buried” are used to refer to the state of being in contact with the electrolyte “soil”.

Cathodic protection systems apply a current to the buried object to counteract the electrochemical corrosion process and thereby mitigate the damage to the object. The protected, buried structures are periodically monitored to determine the level of cathodic protection in order to assure that the protection current is sufficient to adequately mitigate the corrosion. The level considered sufficient is determined by application of one of the industry standards and is based upon measurement of the potential difference between the buried metal object and a reference electrode placed in contact with the surrounding soil. Cathodic protection systems and their measurements are described in U.S. Pat. Nos. 5,814,982; 6,107,811 and the patent to soon issue on U.S. patent application Ser. No. 10/115,796, which are herein incorporated by reference, and in many other patents.

One problem with measuring that potential is that the potential between the reference electrode and the buried object consists of the sum of (1) the electrochemical potential at the interface of the buried object and the soil, (2) the potential drop through the soil resulting from the electrical current of the voltage measuring circuit flowing through a resistive soil material and (3) the electrochemical potential at the interface between the reference electrode and the soil. However, the potential sought to be measured is the sum of the electrochemical potentials at the interfaces and arises from the existence of the equivalent of an electrochemical battery at these interfaces. Therefore, the potential drop across the soil introduces an error into the voltage measurement and that potential drop may be large compared to the potentials sought to be measured. For example, soil resistance, when taking such measurements, typically is in the broad range extending from a few hundred ohms to 500 kohms.

The potential sought to be measured is typically on the order of millivolts. An accuracy of 5 mV is generally acceptable; however, one strives to measure within 1 mV. Accurate measurements are needed in order to assure that effective protection exists while not incurring the unnecessary cost and waste of electrical energy caused by applying excessive current from the cathodic protection circuit.

Eliminating the problem of the voltage drop across a high impedance is conventionally solved by making the voltage measurements using a high impedance voltage measuring circuit in which the input impedance of the voltage measuring circuit is much higher than the impedance of the circuit being measured. This solution applies a voltage divider principle which views the impedance in the measured circuit and the impedance in the voltage measuring circuit as a voltage divider with the voltage measurement being made across the impedance of the voltage measuring circuit. If the input impedance of the voltage measuring circuit is much greater than the impedance of the circuit being measured, the voltage measured across the input impedance of the voltage measuring circuit will be approximately equal to the voltage across the voltage divider, which is the actual voltage in the circuit being measured.

The disadvantage of this principle is that the measurement is only an approximation and therefore is still inaccurate. For example, if the soil resistance is 10% of the voltage metering circuit impedance, a measurement of 1 volt would include an error of 100 millivolts. The prior art has therefore developed voltage metering circuits with a much higher impedance in order to reduce this error further. For example, the input impedance can be increased to 100 times the soil impedance, or the impedance of any circuit being measured, to decrease the error to 1%. However, such voltage meters do not return to zero volts when the circuit is opened (no voltage being measured) which creates a problem for an operator in the field taking a measurement. Additionally, such high impedance voltage measuring devices are susceptible to electrical noise because the high impedance results in the current drawn through the circuit being very small. Therefore, electrical interference coupled to or imposed on the circuit is significant compared to the current being drawn and therefore introduces additional errors into the measurements. These inaccuracies are a particular problem where voltage measurements are sought which are accurate to within a millivolt or a few millivolts.

One prior art attempt to minimize these disadvantages of a high input impedance voltage measuring circuit is to provide multiple, alternately selectable resistances in the voltage metering circuit by which the input impedance of the voltage measuring circuit can be switched to any one of multiple input impedances. The user then takes a sequence of measurements beginning with the lowest impedance and then at sequentially increased impedances. If the users see that there is no significant change in the measurement in going from one input impedance to the next highest input impedance, he concludes that the measurement at the lower impedance is sufficiently accurate. However, this approach is a compromise with accuracy because it is still has the above described deficiencies of the voltage divider concept and has only minimized these deficiencies. In a similar approach, the user plots the measurement values for each input impedance on a graph and then extrapolates from the graph to conclude that the most accurate measurement is near the knee of the curve where there is only a minor change in the measured values.

It is, therefore, an object and feature of the invention to provide a voltage measuring circuit which has a lower input impedance so it is not so affected by coupled electrical noise and also to provide such a circuit that provides more accurate measurements.

### (f) BRIEF SUMMARY OF THE INVENTION

The invention applies a method for measuring the potential of a voltage source in a measured circuit having an impedance in the measured circuit. A first potential is measured by connecting a voltage measuring circuit, having a first input impedance, across the measured circuit and the first potential is stored in a computer memory device or otherwise recorded. The input impedance of the voltage measuring circuit is then changed or switched to a second input impedance and a second potential is measured with the voltage measuring circuit connected across the measured circuit and the second potential is stored. Simultaneous equations, describing the connected measured and voltage measuring circuits, are then solved for the potential of the voltage source using the first and second measured potentials.

The apparatus for measuring the potential of a voltage source in a measured circuit having an impedance in the measured circuit includes a voltage measuring circuit having an input impedance including a switchable impedance network in the voltage measuring circuit for varying the input impedance of the voltage measuring circuit to a plurality of input impedance values. A microcontroller is connected to the voltage measuring circuit for switching the input impedance, for recording measured potentials at a plurality of input impedances, for solving the simultaneous equations, the equations describing the connected measured and voltage measuring circuits, for the potential of the voltage source, and for outputting a signal representing the potential of the voltage source.

### (g) BRIEF DESCRIPTION OF THE SEVERAL VIEWS OF THE DRAWINGS

FIG. 1 is a schematic diagram illustrating the principles of the invention.

FIG. 2 is a block diagram of the preferred embodiment of the invention.

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose. For example, the word connected or term similar thereto are often used. They are not limited to direct connection, but include connection through other circuit elements where such connection is recognized as being equivalent by those skilled in the art. In addition, many circuits are illustrated which are of a type which perform well known operations on electronic signals. Those skilled in the art will recognize that there are many, and in the future may be additional, alternative circuits which are recognized as equivalent because they provide the same operations on the signals.

### (h) DETAILED DESCRIPTION OF THE INVENTION

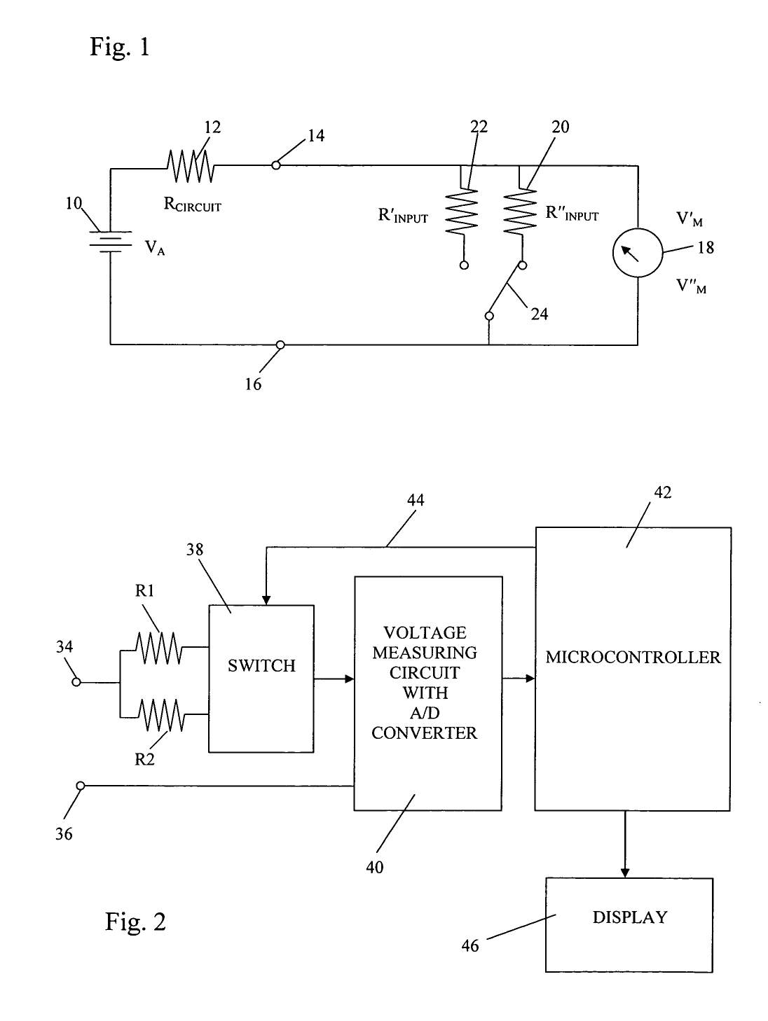

FIG. 1 is a schematic diagram illustrating the principle of the invention. The sum of the electrochemical potentials at the above described interfaces is represented by a battery 10. A resistor 12 represents the soil resistance so that the terminals 14 and 16 represent the conductive connections to the buried object, such as a pipeline, and the reference electrode. The remaining circuit represents the voltage measuring circuit connected to the terminals 14 and 16.

The voltage measuring circuit has a voltage measuring device 18 and two resistors 20 and 22 connected to a switch 24 forming an impedance switching network. While the voltage measuring device 18 could be a voltmeter, it preferably is a voltage measuring circuit which senses the voltage at the terminals 14 and 16 and converts the voltage to a digital data format. The switch 24 switches the impedance switching network to alternatively connect either the resistor 20 or the resistor 22 in the circuit so that the input impedance of the voltage measuring circuit is switched between two alternatively selectable values. The voltage measuring device 18 may also have an input impedance which will contribute to the input impedance of the voltage measuring circuit. However, the input impedance of the voltage measuring circuit will still be switchable between at least two input impedance values.

As will be apparent to those skilled in the electronic arts, there are numerous ways to switch the resistance or impedance of a circuit between two or more values. A single pole, multiple throw switch can alternatively connect any one of multiple resistors into the circuit. For example, a single pole, double throw switch can switch either of two resistors into the circuit with the other resistor being left unconnected at one end so that it has no effect upon the circuitry. That is illustrated in FIG. 1. Alternatively, a single resistor can be switched into an out of parallel connection to another resistor so that the resistance of the circuit is that of one resistor when the second resistor is disconnected and the resistance is that of the parallel combination of the two resistors when the second resistor is switched into parallel connection with the first resistor. As another alternative, a potentiometer can be used and smoothly and continuously vary the resistance in the circuit over a range of resistance values. Other electronic equivalents of a potentiometer or variable resistance can be used to vary the resistance to multiple values, either as an analog, continuously variable resistance or as a digital, stepwise variable resistance.

As also apparent to those skilled in the electronic arts, there are a variety of known switches available for use. They include manually actuated switches and switching circuits, commonly formed by transistors. Such switching circuits are well known to be capable of being controlled by control circuits including a microcontroller.

Those skilled in the electronic arts will also recognize that the principles of Thevenin and Norton equivalent circuits are applicable to the present invention. These principles make it apparent that a series connected impedance and voltage source have an equivalent circuit in the form of a parallel connected impedance and current source. Consequently, there are both Thevenin and Norton equivalents of the circuit and its components that are illustrated in FIG. 1.

FIG. 2 is a block diagram illustrating a preferred implementation of the invention and shows only the voltage measuring circuit with input terminals 34 and 36. The input terminal 34 is connected to resistors R1 and R2 which in turn are connected to an electronic switching circuit 38 so they together form the switchable impedance network. The output of the switchable impedance network is connected to a voltage measuring circuit 40 with an output analog to digital converter. Such circuits are commonly used in modern digital multimeters. The output of the A/D converter applies the measured voltage in digital data format to a microcontroller 42. The microcontroller 42 also has a connection 44 to the switch 38 for controllably switching the switch 38 and a connection to a display 46 for displaying both output data, such as the voltage source voltage, and optionally for control purposes.

The microcontroller 42 is the circuitry that performs the logic functions, data processing functions and control functions according to a control algorithm. The microcontroller can be a conventional or commercially available microcontroller, that is a special purpose computer for controlling equipment and having a data processor, data storage and input and output connections commonly associated with computing circuits. Such a microcontroller performs the logic, data processing, and control functions with stored software as is well known in the art. Alternatively, the microcontroller can be a programmable logic device (PLD) or a combination of a conventional microcontroller, and a PLD or some discrete logic circuitry, such as AND, OR, NOR and NAND gates that, together, perform the logic, data processing, and control functions with those functions being distributed between hardwired, logic circuits and the commercial microcontroller. A microcontroller based control system would ordinarily also include the usual interfaces or buffers and other conventionally known computer circuitry. Because the functions can be performed by a conventional microcontroller or other known logic devices or by a combination of them with the logic functions distributed between them, the term “microcontroller” is used, unless otherwise indicated, to include any of these implementations of special purpose computing or logic circuits for inputting and processing input data according to a control algorithm and providing output control and display signals.

The operation of an embodiment of the invention is based on the following relationship between the actual (true) voltage and the measured values:

$${V}_{M} = {V}_{A} \times ( \frac{{R}_{INPUT}}{{R}_{INPUT} + {R}_{CIRCUIT}} ) ,$$

where:
V_{M}—measured voltage
V_{A}—[V_{ACTUAL}] actual (true) voltage of the voltage source of the circuit being measured
R_{INPUT}—input impedance of the measuring circuit
R_{CIRCUIT}—resistance of the measured circuit

The equation shows that the V_{M}≈V_{A} when R_{INPUT}>>R_{CIRCUIT}. The common approach in commercially available measurement devices (such as Fluke or MC Miller brand digital multimeters), as described above, is to increase the input impedance so that R_{INPUT}>>R_{CIRCUIT} to achieve the desired ratio between the two resistance values in order to approximate the actual potential by the measured potential.

However, the invention recognizes that, of the four variables, two are unknown (R_{CIRCUIT} and V_{ACTUAL}). Therefore, in order to obtain these, a second equation is necessary to solve for the unknown variables. Therefore, if two measurements are taken to obtain two V_{M} values (V′_{M} and V″_{M}) at two different R_{INPUT} resistance values (R′_{INPUT} and R″_{INPUT}), the following system of two simultaneous equations is constructed:

$$\begin{matrix}{V}_{M}^{′} = {V}_{A} \times ( \frac{{R}_{INPUT}^{′}}{{R}_{INPUT}^{′} + {R}_{CIRCUIT}} ) \\ {V}_{M}^{″} = {V}_{A} \times ( \frac{{R}_{INPUT}^{″}}{{R}_{INPUT}^{″} + {R}_{CIRCUIT}} )\end{matrix} \}$$

Solution of the above simultaneous equations yields the value of V_{A}. This approach eliminates the need for the measurement device to have the input impedance significantly exceeding that of the measured circuit. The solved V_{A} value is equal to the value measured with a virtual instrument having infinite input impedance. The solved equation is shown below:

$${V}_{A} = {V}_{M}^{′} \times {V}_{M}^{″} ( \frac{{R}_{INPUT}^{′} - {R}_{INPUT}^{″}}{{V}_{M}^{″} {R}_{INPUT}^{′} - {V}_{M}^{′} {R}_{INPUT}^{″}} ) = \frac{{R}_{INPUT}^{′} - {R}_{INPUT}^{″}}{\frac{{R}_{INPUT}^{′}}{{V}_{M}^{′}} - \frac{{R}_{INPUT}^{″}}{{V}_{M}^{″}}} .$$

Thus, although neither the measured value V′_{M} nor V″_{M} are accurate measurements of V_{A}, the value of V_{A} found by solving the equations is. This means that it is not necessary that any value of R_{INPUT} be far larger than R_{CIRCUIT}. Consequently, the inaccuracies which have arisen from that requirement are not present with embodiments of the invention.

The control algorithm or software of the microcontroller begins the measurement of the potential of a voltage source in a measured circuit by first measuring a first potential with the voltage measuring circuit connected across the measured circuit. That first potential is stored. The microcontroller then switches the input impedance of the voltage measuring circuit and measures a second potential and stores (records) the second potential. The above simultaneous equations are then solved for the potential V_{A} of the voltage source. The voltage V_{A} can then be displayed and may be used for additional data processing.

The principles of the invention may also be applied to solving more than two simultaneous equations. Additional resistors or other devices with additional impedances may also be switchable into the circuit and additional measurements taken using these additional impedances. This will provide further improved accuracy by providing additional equations and all of the equations can be solved simultaneously. Alternatively, the equations can be solved in sets and known error correction algorithms applied to the solutions to select or compute the most accurate measurement.

While certain preferred embodiments of the present invention have been disclosed in detail, it is to be understood that various modifications may be adopted without departing from the spirit of the invention or scope of the following claims.

1. A method for measuring the potential of a voltage source in a measured circuit having an impedance in the measured circuit, the method comprising:
(a) measuring a first potential by connecting a voltage measuring circuit, having a first input impedance, across the measured circuit and recording the first potential;
(b) changing the input impedance of the voltage measuring circuit;
(c) measuring a second potential with the voltage measuring circuit connected across the measured circuit, the voltage measuring circuit having the second input impedance and recording the second potential; and
(d) solving simultaneous equations, describing the connected measured and voltage measuring circuits, for the potential of the voltage source.

2. A method in accordance with claim 1 wherein the input impedance is changed by switching a resistive circuit element from one state to a second state, the states being connected in the measuring circuit and disconnected from the measuring circuit.

3. A method in accordance with claim 1 wherein at least an additional measurement is made for at least one additional input impedance.

4. A method in accordance with claim 1 where the simultaneous equations solved are:
$$\begin{matrix}{V}_{M}^{′} = {V}_{A} \times ( \frac{{R}_{INPUT}^{′}}{{R}_{INPUT}^{′} + {R}_{CIRCUIT}} ) \\ {V}_{M}^{″} = {V}_{A} \times ( \frac{{R}_{INPUT}^{″}}{{R}_{INPUT}^{″} + {R}_{CIRCUIT}} )\end{matrix} \}$$
wherein
V′_{M} is the measured voltage at the first measured impedance
V″_{M} is the measured voltage at the second measured impedance
V_{A}—actual (true) voltage
R′_{INPUT} is the first input impedance of the measurement device
R″_{INPUT} is the second input impedance of the measurement device
R_{CIRCUIT}—resistance of the measured circuit

5. A method in accordance with claim 4 wherein the input impedance is changed by switching a resistive circuit element from one state to a second state, the states being connected in the measuring circuit and disconnected from the measuring circuit.

6. A method in accordance with claims 1 or 2 or 3 or 4 or 5 wherein the circuit being measured includes a metal object buried in soil and a reference electrode in contact with the soil and wherein the voltage measuring circuit is electrically connected between the metal object and the reference electrode.

7. An apparatus for measuring the potential of a voltage source in a measured circuit having an impedance in the measured circuit, the apparatus comprising:
(a) a voltage measuring circuit having an input impedance;
(b) a switchable impedance network in the voltage measuring circuit for varying the input impedance to a plurality of input impedance values;
(c) a microcontroller connected to the voltage measuring circuit for switching the input impedance, for recording measured potentials at a plurality of input impedances, for solving simultaneous equations, the equations describing the connected measured and voltage measuring circuits, for the potential of the voltage source, and for outputting a signal representing the potential of the voltage source.

8. An apparatus in accordance with claim 7 wherein the switchable impedance network comprises a plurality of resistors at least one of the resistors being connected to a switch for switching said one resistor alternatively in and out of the circuit.

9. An apparatus in accordance with claim 8 wherein the switchable impedance network comprises a plurality of resistors, each resistor connected to a switch and being alternatively switchable into the circuit.

10. An apparatus in accordance with claim 7 or 8 or 9 wherein the microcontroller is programmed to solve equations which are substantially:
$$\begin{matrix}{V}_{M}^{′} = {V}_{A} \times ( \frac{{R}_{INPUT}^{′}}{{R}_{INPUT}^{′} + {R}_{CIRCUIT}} ) \\ {V}_{M}^{″} = {V}_{A} \times ( \frac{{R}_{INPUT}^{″}}{{R}_{INPUT}^{″} + {R}_{CIRCUIT}} )\end{matrix} \}$$
wherein
V′_{M} is the measured voltage at the first measured impedance
V″_{M} is the measured voltage at the second measured impedance
V_{A}—actual (true) voltage
R′_{INPUT} is the first input impedance of the measurement device
R″_{INPUT} is the second input impedance of the measurement device
R_{CIRCUIT}—resistance of the measured circuit
